(19) United States
(12) Patent Application Publication
(10) Pub. No.: US 2025/0040227 A1
(43) Pub. Date: Jan. 30, 2025

(54) SEMICONDUCTOR DEVICE AND METHOD FOR FABRICATING THE SAME

(71) Applicant: UNITED MICROELECTRONICS CORP., Hsin-Chu City (TW)

(72) Inventors: Kuan-Liang Liu, Hsinchu County (TW); Szu-Han Huang, New Taipei City (TW)

(73) Assignee: UNITED MICROELECTRONICS CORP., Hsin-Chu City (TW)

(21) Appl. No.: 18/237,401

(22) Filed: Aug. 23, 2023

(30) Foreign Application Priority Data
Jul. 28, 2023 (TW) 112128287

(51) Int. Cl. H01L 29/423; H01L 29/66; H01L 29/78; H01L 29/786

(52) U.S. Cl. CPC H01L 29/42364; H01L 29/66795; H01L 29/785; H01L 29/78618

(57) ABSTRACT

A semiconductor device includes a gate structure, an insulating layer and two source/drain regions. A portion of the gate structure is embedded in a substrate. The insulating layer is disposed between the portion of the gate structure and the substrate and encompasses the portion of the gate structure. The two source/drain regions are disposed in the substrate and respectively located at two sides of the gate structure.

### BACKGROUND OF THE INVENTION

### 1. Field of the Invention

The present disclosure relates to the field of semiconductor devices, and more particularly, to a semiconductor device and a method for fabricating the same.

### 2. Description of the Prior Art

In order to reduce production cost, improve competitive advantages and meet the needs of various products, the size of semiconductor devices may be reduced, or semiconductor devices with different driving voltages may be integrally formed in a same chip.

However, as the size of semiconductor devices reduces, the probability of leakage current increases. In addition, semiconductor devices with different driving voltages integrally formed in a same chip may cause some process problems. For example, a medium voltage device or a high voltage device usually includes a thicker gate dielectric layer to sustain a higher operation voltage. However, the thicker gate dielectric layer may cause the gate height of the medium voltage device or the high voltage device to be different from that of other devices, which may increase the difficulty of process control. Therefore, how to improve the semiconductor device and method for fabricating the same has become an important issue for the relevant industry.

### SUMMARY OF THE INVENTION

According to one aspect of the present disclosure, a semiconductor device includes a gate structure, an insulating layer and two source/drain regions. A portion of the gate structure is embedded in a substrate. The insulating layer is disposed between the portion of the gate structure and the substrate and encompasses the portion of the gate structure. The two source/drain regions are disposed in the substrate and respectively located at two sides of the gate structure.

According to another aspect of the present disclosure, a semiconductor device includes a substrate, a fin structure, a first insulating structure, a first gate structure, a second gate structure and an insulating layer. The substrate has a first region and a second region. The fin structure is disposed in the first region. The first insulating structure is disposed in the first region and surrounds the fin structure, wherein a portion of the fin structure protrudes from the first insulating structure. The first gate structure is disposed in the first region and on the fin structure. The second gate structure is disposed in the second region, wherein a portion of the second gate structure is embedded in the substrate. The insulating layer is disposed between the portion of the second gate structure and the substrate and encompasses the portion of the second gate structure.

According to yet another aspect of the present disclosure, a method for fabricating a semiconductor device is disclosed. The method includes steps as follows. A substrate having a first region and a second region is provided. A fin structure and a first insulating structure are formed in the first region, wherein the first insulating structure surrounds the fin structure. A temporary insulating structure is formed in the second region. A portion of the first insulating structure is removed, so that a portion of the fin structure protrudes from the first insulating structure. A portion of the temporary insulating structure is removed to form an insulating layer and a recess in the substrate. A first gate structure is formed on the fin structure. A second gate structure is formed on the insulating layer and in the recess.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1, FIG. 2, FIG. 3 and FIG. 4 are schematic diagrams showing steps for fabricating a semiconductor device according to one embodiment of the present disclosure.

FIG. 5 is a schematic top view of a semiconductor device according to one embodiment of the present disclosure.

FIG. 6 is a schematic cross-sectional view of a semiconductor device according to another embodiment of the present disclosure.

FIG. 7 is a schematic cross-sectional view of a semiconductor device according to further another embodiment of the present disclosure.

FIG. 8 is a schematic cross-sectional view of a semiconductor device according to yet another embodiment of the present disclosure.

FIG. 9 is a diagram showing a relationship of leakage current and voltage of an example according to the present disclosure and a comparative example.

FIG. 10 is a diagram showing a relationship of current and voltage of an example according to the present disclosure and a comparative example.

### DETAILED DESCRIPTION

In the following detailed description of the embodiments, reference is made to the accompanying drawings which form a part thereof, and in which is shown by way of illustration specific embodiments in which the disclosure may be practiced. In this regard, directional terminology, such as up, down, left, right, front, back, bottom or top is used with reference to the orientation of the Figure(s) being described. The elements of the present disclosure can be positioned in a number of different orientations. As such, the directional terminology is used for purposes of illustration and is in no way limiting. In addition, identical numeral references or similar numeral references are used for identical elements or similar elements in the following embodiments.

Hereinafter, for the description of “the first feature is formed on or above the second feature”, it may refer that “the first feature is in contact with the second feature directly”, or it may refer that “there is another feature between the first feature and the second feature”, such that the first feature is not in contact with the second feature directly.

It is understood that, although the terms first, second, etc. may be used herein to describe various elements, regions, layers and/or sections, these elements, regions, layers and/or sections should not be limited by these terms. These terms may be only used to distinguish one element, region, layer and/or section from another element, region, layer and/or section. Terms such as “first,” “second,” and other numerical terms when used herein do not imply a sequence or order unless clearly indicated by the context. Thus, a first element, region, layer and/or section discussed below could be termed a second element, region, layer and/or section without departing from the teachings of the embodiments. The terms used in the claims may not be identical with the terms used in the specification, but may be used according to the order of the elements claimed in the claims.

According to one embodiment of the present disclosure, a method for fabricating a semiconductor device includes steps as follows. A substrate having a first region and a second region is provided. A fin structure and a first insulating structure are formed in the first region, wherein the first insulating structure surrounds the fin structure. A temporary insulating structure is formed in the second region. A portion of the first insulating structure is removed, so that a portion of the fin structure protrudes from the first insulating structure. A portion of the temporary insulating structure is removed to form an insulating layer and a recess in the substrate. A first gate structure is formed on the fin structure. A second gate structure is formed on the insulating layer and in the recess. The method for fabricating the semiconductor device may further include the following step. A second insulating structure is formed in the second region, wherein the second insulating structure surrounds the second gate structure.

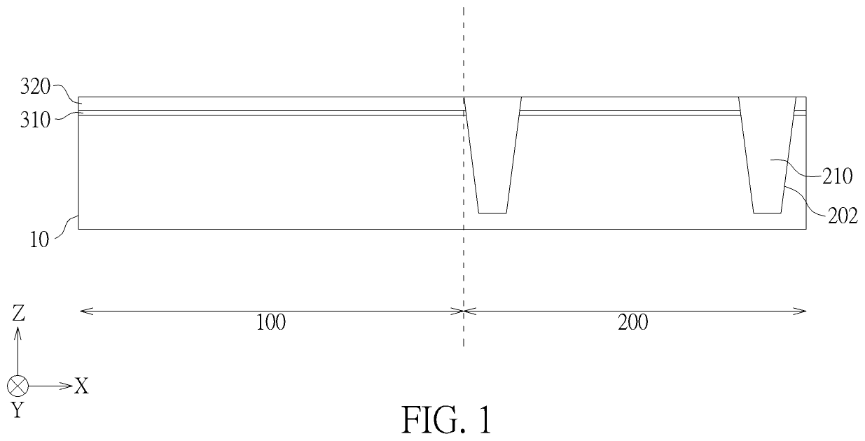

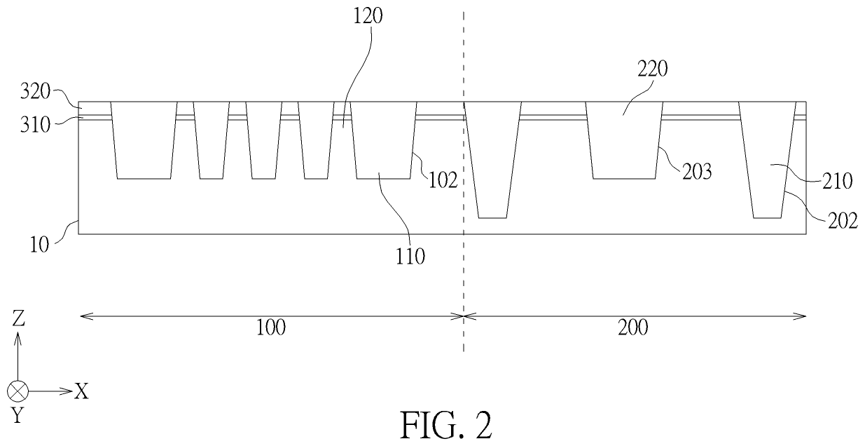

Please refer to FIG. 1 to FIG. 4, which are schematic diagrams showing steps for fabricating a semiconductor device 1 according to one embodiment of the present disclosure, and are used to exemplarily illustrate the aforementioned method. In FIG. 1, a substrate 10 is provided. The substrate 10 has a first region 100 and a second region 200. The substrate 10 may be a silicon substrate, an epitaxial silicon substrate, a silicon carbide substrate or a silicon on insulator (SOI) substrate. The first region 100 may be, for example, a low voltage device region. The second region 200 may be, for example, a medium and high voltage device region. In general, taking a display chip as an example, the low voltage device region includes, for example, logic circuits, and an operation voltage thereof is less than or equal to 5 volts, and preferably within 1.5 volts. The operation voltage of the electronic devices disposed in the medium and high voltage device region is greater than 5 volts, and is usually greater than 10 volts. For example, a driving device of the display chip which requires a higher voltage to drive other devices of the display chip is the medium voltage device or the high voltage device of the present disclosure. Next, a first hard mask 310 and a second hard mask 320 are sequentially formed on the substrate 10. A material of the first hard mask 310 may include an oxide such as silicon dioxide, and a material of the second hard mask 320 may include a nitride such as silicon nitride, but not limited thereto. Next, an insulating structure 210 is formed in the second region 200. For example, the first hard mask 310 and the second hard mask 320 on the second region 200 can be firstly patterned and a recess 202 is formed in the second region 200 by a lithography process and an etching process, then an insulating structure 210 is formed in the second region 200 by a deposition process and a planarization process such as chemical mechanical polishing (CMP) process. The insulating structure 210 may be, for example, a shallow trench isolation (STI). A material of the insulating structure 210 may include a dielectric material such as silicon dioxide.

Next, as shown in FIG. 2, fin structures 120 and an insulating structure 110 are formed in the first region 100, and a temporary insulating structure 220 is formed in the second region 200. The insulating structure 110 and the temporary insulating structure 220 can be formed in a same step. For example, the first hard mask 310 and the second hard mask 320 on the first region 100 and the second region can be firstly patterned by a lithography process and an etching process, and the fin structures 120 and a recess 102 are formed in the first region 100 and a recess 203 is formed in the second region 200. Alternatively, the fin structures 120 and the recesses 102 and 203 can be formed by a sidewall image transfer (SIT) technology. The sidewall image transfer technology is well known in the art, and is omitted herein. Next, the insulating structure 110 is formed in the first region 100 and the temporary insulating structure 220 is formed in the second region 200 by a deposition process and a planarization process, wherein the insulating structure 110 surrounds the fin structures 120. The insulating structure 110 may be, for example, a shallow trench isolation. Materials of the insulating structure 110 and the temporary insulating structure 220 may include a dielectric material such as silicon dioxide. In the embodiment, the insulating structure 210 is formed first, and then the insulating structure 110 and the temporary insulating structure 220 are formed, but the present disclosure is not limited thereto. In other embodiment, the insulating structure 110 and the temporary insulating structure 220 may be formed first, and then the insulating structure 210 is formed.

Next, as shown in FIG. 3, a portion of the insulating structure 110 is removed, so that a portion 121 of each of the fin structures 120 protrudes from the insulating structure 110. For example, a patterned mask (not shown) may be formed first, and then a portion of the insulating structure 110 may be removed by a lithography process and an etching process to form the recess 130, so that the portion 121 of each of the fin structure 120 protrudes from the insulating structure 110. Next, a portion of the temporary insulating structure 220 is removed to form an insulating layer 240 and a recess 230 in the substrate 10, wherein the insulating layer 240 includes a first layer 241 and a second layer 242. Next, the first hard mask 310, the second hard mask 320, a portion of the insulating structure 210 and a portion of the insulating layer (herein, a portion of the second layer 242) are removed by a planarization process, so that the insulating structure 210 and the insulating layer 240 are aligned with a top surface 201 of substrate 10 in the second region 200. In the embodiment, the recess 130 is formed first, and then the recess 230 is formed, but the present disclosure is not limited thereto. In other embodiment, the recess 230 may be formed first, and then the recess 130 is formed.

Next, as shown in FIG. 4, a gate dielectric layer 140 may be formed on the fin structure 120 first. For example, a thermal oxidation process can be performed in an oxygen-containing environment, so that a surface layer of the portion 121 of the fin structure 120 protruding from the insulating structure 110 can be oxidized to form a gate dielectric layer 140. Since a thickness t1 of the gate dielectric layer 140 is very thin, a top surface 122 of the fin structure 120 may be slightly lower than the top surface 201 of the substrate 10 in the second region 200 or substantially aligned with the top surface 201 of the substrate 10 in the second region 200 after the thermal oxidation process. The thermal oxidation process may include in-situ steam generation (ISSG) oxidation process, wet furnace oxidation process, or dry furnace oxidation process, but not limited thereto. Alternatively, a dielectric material can be deposited on the top surface 122 of the fin structure 120 to form the gate dielectric layer 140. In this case, the top surface 122 of the fin structure 120 is substantially aligned with the top surface 201 of the substrate 10 in the second region 200. A material of the gate dielectric layer 140 may include an oxide or a nitride. The oxide may be, for example, silicon dioxide. The nitride may be, for example, silicon nitride, but not limited thereto.

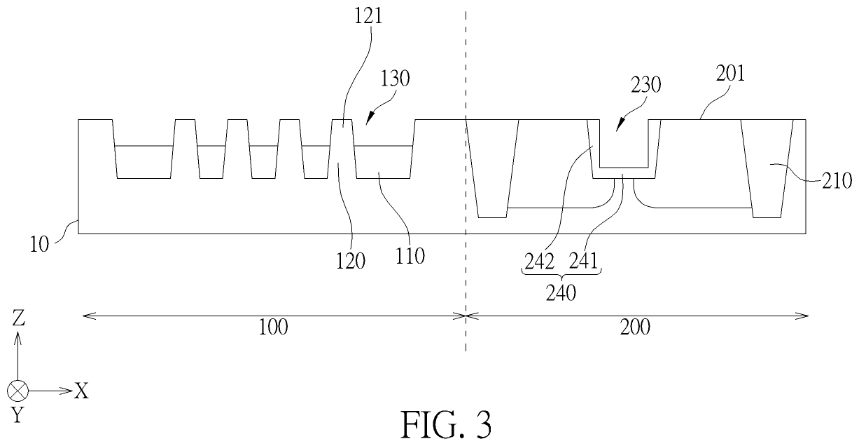

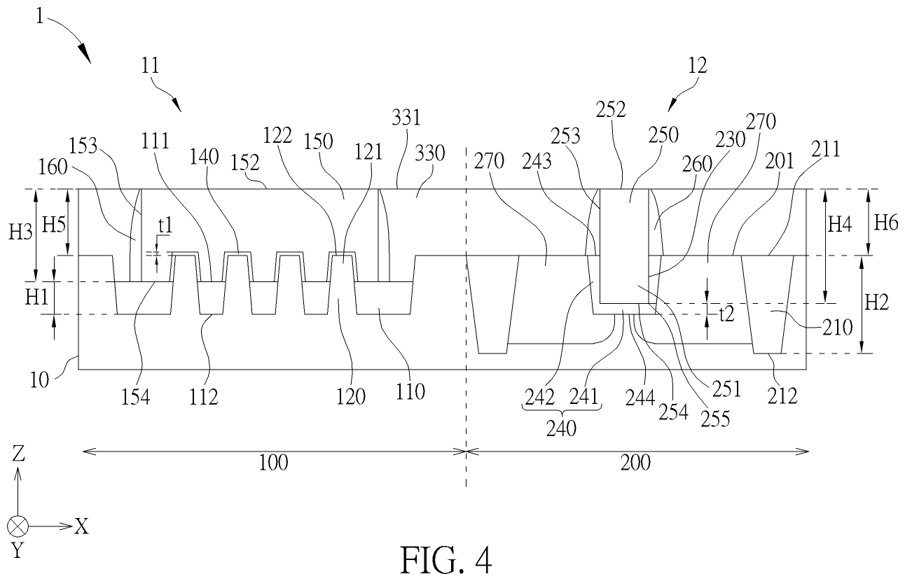

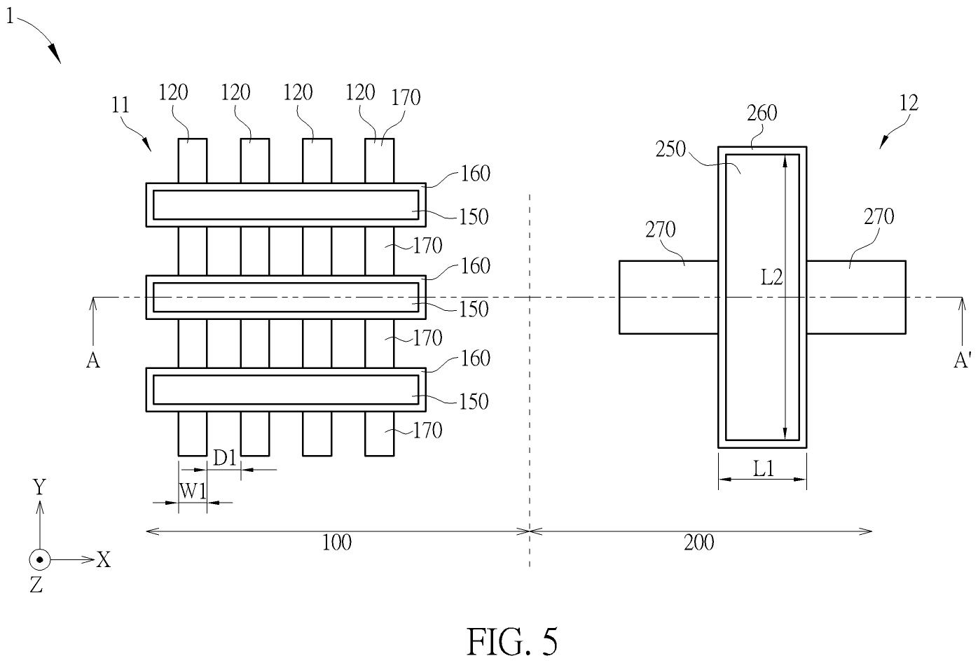

Next, a gate structure 150 is formed on the fin structure 120, and a gate structure 250 is formed on the insulating layer 240 and in the recess 230. The insulating structure 210 surrounds the gate structure 250. The gate structures 150 and 250 are formed in a same step. For example, a gate material may be deposited on the substrate 10 by a deposition process, and then a portion of the gate material is removed by a patterning process and a planarization process to remove a portion of the gate material to form the gate structures 150 and 250. A material of the gate structures 150 and 250 may include a non-metallic conductive material such as polycrystalline silicon. Next, light doped drains (LDDs) (not shown) may be formed in the portions of the fin structure 120 located at two sides of the gate structure 150. Next, light doped drains (not shown) may be formed in the portions of the substrate 10 located at two sides of the gate structure 250. Next, a spacer 160 is formed to surround a side surface 153 of the gate structure 150, and a spacer 260 is formed to surround a side surface 253 of the gate structure 250. Materials of the spacers 160 and 260 may independently include oxides and/or nitrides, such as silicon dioxide, silicon nitride, silicon oxynitride or silicon carbonitride. Next, source/drain regions 170 (shown in FIG. 5) may be formed in the portions of the fin structure 120 located at two sides of the gate structure 150. Next, source/drain regions 270 may be formed in the portions of the substrate 10 located at two sides of the gate structure 250. The dopants of the source/drain regions 170 and 270 may be adjusted depending on the semiconductor devices 11 and 12 being applied to n-type metal oxide semiconductor (NMOS) transistors or p-type metal oxide semiconductor (PMOS) transistors. For example, when the semiconductor devices 11 and 12 are applied to the NMOS transistors, the source/drain regions 170 and 270 may have N-type impurities, such as arsenic and phosphorus. When the semiconductor devices 11 and 12 are applied to the PMOS transistors, the source/drain regions 170 and 270 may have p-type impurities, such as boron and indium. Afterward, a dielectric layer 330 may be formed on the substrate 10. For example, a dielectric material may be deposited on the substrate 10, and then a portion of the dielectric material is removed by a planarization process, so that a top surface of the remaining dielectric material may be aligned with the top surface 152 of the gate structure 150 and the top surface 252 of the gate structure 250 to complete the fabrication of the dielectric layer 330. A material of the dielectric layer 330 may include silicon dioxide or tetraethoxysilane (TEOS), but not limited thereto. Thereby, the fabrication of the semiconductor device 1 is completed.

As shown in FIG. 4, the semiconductor device 1 includes the semiconductor device 11 and the semiconductor device 12. The semiconductor device 11 is a non-planar transistor, and the semiconductor device 12 is a planar transistor. Compared with a semiconductor device having the non-planar transistor and the planar transistor arranged on different layers, the method for fabricating the semiconductor device according to the present disclosure can arrange the non-planar transistor and the planar transistor on a same layer, which is beneficial to improve the pattern loading uniformity.

The aforementioned film layers, such as the first hard mask 310, the second hard mask 320, the insulating structures 110 and 210, the temporary insulating structure 220, the gate dielectric layer 140, the gate structures 150 and 250, the spacers 160 and 260, and the dielectric layer 330, may be formed by any suitable methods. For example, the methods may be, but are not limited to, molecular-beam epitaxy (MBE), chemical vapor deposition (CVD), metal organic chemical vapor deposition (MOCVD), hydride vapor phase epitaxy (HVPE), atomic layer deposition (ALD).

Please refer to FIG. 4 and FIG. 5 simultaneously. FIG. 4 shows a schematic cross-sectional view of the semiconductor device 1 according to one embodiment of the present disclosure. FIG. 5 is a schematic top view of the semiconductor device 1 according to one embodiment of the present disclosure. FIG. 4 a schematic cross-sectional view taken along line A-A′ in FIG. 5. For the sake of simplification, only the fin structures 120, the gate structures 150, the spacers 160, the source/drain regions 170 of the first region 100 and the gate structure 250, the spacer 260 and the source/drain regions 270 of the second region 200 are shown in FIG. 5, and other elements are omitted.

The semiconductor device 1 include the substrate 10, the fin structures 120, the insulating structure 110, the gate structure 150, the gate structure 250 and the insulating layer 240. The substrate 10 has the first region 100 and the second region 200. The fin structures 120 are disposed in the first region 100. The first insulating structure 110 is disposed in the first region 100 and surrounds the fin structures 120. A portion 121 of the fin structure 120 protrudes from the first insulating structure 110. The gate structure 150 is disposed in the first region 100 and on the fin structures 120. The gate structure 250 is disposed in the second region 200, and a portion 251 of the gate structure 250 is embedded in the substrate 10. The insulating layer 240 is disposed between the portion 251 of the gate structure 250 and the substrate 10 and encompasses the portion 251 of the gate structure 250. The insulating layer 240 includes a first layer 241 and a second layer 242. The first layer 241 may be a horizontal portion of the insulating layer 240, and the second layer 242 may be a vertical portion of the insulating layer 240. The first layer 241 is disposed on the bottom surface 254 of the gate structure 250, and the second layer 242 is disposed on the side surface 253 of the gate structure 250. The semiconductor device 1 may further includes an insulting structure 210, a gate dielectric layer 140, the spacers 160 and 260, the dielectric layer 330 and the source/drain regions 170 and 270. The insulating structure 210 is disposed in the second region 200 and surrounds the gate structure 250. The gate dielectric layer 140 is disposed on the portion 121 of the fin structure 120 protruding from the insulating structure 110 and is between the fin structure 120 and the gate structure 150. The spacer 160 surrounds the side surface 153 of the gate structure 150, and the spacer 260 surrounds the side surface 253 of the gate structure 250. The dielectric layer 330 is disposed on the substrate 10. A top surface 331 of the dielectric layer 330 is aligned with the top surface 152 of the gate structure 150 and the top surface 252 of the gate structure 250. The source/drain regions 170 (shown in FIG. 5) are disposed in the portions of the fin structure 120 located at two sides of the gate structure 150. The source/drain regions 270 are disposed in the portions of the substrate 10 located at two sides of the gate structure 250.

The insulating structure 110 has a height H1, the insulating structure 210 has a height H2, and the height H2 is greater than the height H1. The substrate 10 may define a normal direction (for example, a direction parallel to the direction Z), the height H1 may be a distance between the top surface 111 and the bottom surface 112 of the insulating structure 110 in the normal direction, and the height H2 may be a distance between the top surface 211 and the bottom surface 212 of the insulating structure 210 in the normal direction. In addition, the top surface 111 of the insulating structure 110 is lower than the top surface 211 of the insulating structure 210, and the bottom surface 112 of the insulating structure 110 is higher than the bottom surface 212 of the insulating structure 210.

As mentioned above, according to the forming method of the gate dielectric layer 140, the top surface 122 of the fin structure 120 may be aligned with the top surface 201 of the substrate 10 in the second region 200 or slightly lower than the top surface 201. A height H3 of the gate structure 150 may be less than or equal to a height H4 of the gate structure 250. The height H3 may be the distance between the top surface 152 and the bottom surface 154 of the gate structure 150 in the normal direction, and the height H4 may be the distance between the top surface 252 and the bottom surface 254 of the gate structure 250 in the normal direction. The top surface 152 of the gate structure 150 may be aligned with the top surface 252 of the gate structure 250. That is, a height H5 of the gate structure 150 protruding from the top surface 201 is the same as a height H6 of the gate structure 250 protruding from the top surface 201. The materials of the gate structures 150 and 250 may include non-metallic conductive materials, such as polycrystalline silicon. In other words, in the embodiment, the materials of the gate structure 150 and the gate structure 250 may be the same. The structures of the gate structure 150 and the gate structure 250 may be different. For example, the height H3 may be different from the height H4. The bottom surface 112 of the insulating structure 110 may be aligned with the bottom surface 244 of the insulating layer 240. The insulating layer 240 may have a U-shaped profile. The top surface 243 of the insulating layer 240 may be aligned with the top surface 201 of the substrate 10 in the second region 200. The thickness of the gate dielectric layer 140, such as the thickness t1 of the second layer 242 is less than the thickness t2 of the insulating layer 240.

More specifically, the semiconductor device 1 includes the semiconductor device 11 and the semiconductor device 12 disposed in the first region 100 and the second region 200 of substrate 10, respectively. With the height H2 of the insulating structure 210 being greater than the height H1 of the insulating structure 110, the semiconductor device 11 may be configured as a low voltage device, and the semiconductor device 12 may be configured as a medium voltage device or a high voltage device. The semiconductor device 11 may include the aforementioned insulating structure 110, fin structures 120, gate dielectric layer 140, gate structures 150, spacers 160, and source/drain regions 170, but not limited thereto. The semiconductor device 12 may include the aforementioned insulating structure 210, insulating layer 240, gate structure 250, spacer 260 and source/drain regions 270, but not limited thereto. The insulating layer 240 may be used as the gate dielectric layer of the gate structure 250. For a conventional semiconductor device having the gate structure of the low voltage device and the gate structure of the medium voltage device/high voltage device being disposed on the top surface of the substrate, the drawback that the height of the gate structure of the medium voltage device/high voltage device is excessively low due to a thicker gate dielectric layer thereof may occur. In the present disclosure, with the insulating layer 240 and the portion 251 of the gate structure 250 being embedded in the substrate 10, it is beneficial to configure the insulating layer 240 with a thicker thickness to sustain a higher driving voltage. Accordingly, the drawback that the height H4 of the gate structure 250 being excessively low can be prevented.

As shown in FIG. 5, the semiconductor device 11 may include four fin structures 120 and three gate structures 150. The numbers of the fin structures 120 and the gate structures 150 are only exemplary and can be flexibly adjusted according to actual needs. The gate structures 150 extend along a first direction (such as the direction X), the fin structures 120 extend along a second direction (such as the direction Y), and the second direction is perpendicular to the first direction. Each of the fin structures 120 has a predetermined width W1 in the first direction, and the fin structures 120 are spaced apart from each other by a predetermined distance D1 along the first direction. In other words, the widths (i.e., the predetermined widths W1) of the four fin structures 120 in the first direction are identical, and the distances (i.e., the predetermined distances D1) between any two adjacent fin structures 120 in the first direction are identical. The predetermined width W1 may be, for example, 10 nm to 40 nm, and the predetermined distance D1 may be, for example, 10 nm to 40 nm. The gate structure 250 extends along the second direction, and the two source/drain regions 270 are disposed at two sides of the gate structure 250 along the first direction. But the present disclosure is not limited thereto. In other embodiment, the gate structure 250 may extend along the first direction, and the two source/drain regions 270 may be disposed at two sides of the gate structure 250 along the second direction. The gate structure 250 has a first length L1 in the first direction (such as the direction X), and the gate structure 250 has a second length L2 in the second direction. The first length L1 may be, for example, 0.5 μm to 10 μm, and the second length L2 may be, for example, 0.2 μm to 10 μm, but not limited thereto.

In the embodiment, the positions of the first region 100 and the second region 200 are only exemplary, and can be flexibly adjusted according to actual needs. For example, in the embodiment, the second region 200 is directly adjacent to the right side of the first region 100 along the first direction (such as the direction X), but the present disclosure is not limited thereto. In other embodiment, the second region 200 may be directly adjacent to the left side of the first region 100 along the first direction. In addition, the first region 100 and the second region 200 may be indirectly adjacent to each other. That is, other devices and/or other regions may be disposed between the first region 100 and the second region 200. In other embodiment, the first region 100 and the second region 200 can be directly or indirectly adjacent to each other along the second direction (such as the direction Y). For example, the position of the second region 200 in FIG. 5 can be changed to directly or indirectly disposed below or above the first region 100 along the second direction, the gate structure 250 can extend along the second direction, and the two source/drain regions 270 are disposed at two sides of the gate structure 250 along the first direction. Alternatively, the gate structure 250 can extend along the first direction, and the two source/drain regions 270 are disposed at two sides of the gate structure 250 along the second direction.

In the present disclosure, when an element extends along a first direction, it refers that a length of the element in the first direction is greater than a length of the element in the second direction perpendicular to the first direction. For example, the gate structure 150 extends along the first direction, which refers that the length of the gate structure 150 in the first direction is greater than the length of the gate structure 150 in the second direction.

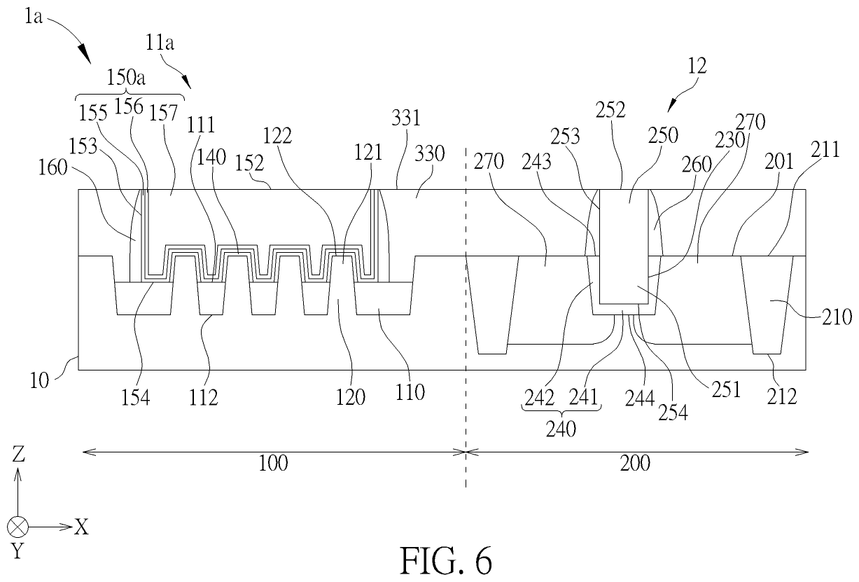

Please refer to FIG. 6, which is a schematic cross-sectional view of a semiconductor device 1a according to another embodiment of the present disclosure. The difference between the semiconductor device 1a and the semiconductor device 1 is that the method for fabricating the semiconductor device 1a further includes a replacement metal gate (RMG) process, which is to replace the non-metallic conductive material of the gate structure 150 in FIG. 4 with a metallic conductive material to form the gate structure 150a. The gate structure 150a may be a single-layer structure or a multi-layer structure. Herein, the gate structure 150a is exemplary a multi-layer structure. The gate structure 150a may include a high dielectric constant (high-k) material layer 155, a work function metal layer 156 and a low-resistance metal layer 157. A material of the high-K material layer 155 may include a dielectric material with a dielectric constant greater than 4, such as hafnium oxide (HfO₂) or hafnium silicon oxide (HfSiO₄), but not limited thereto. A material of the work function metal layer 156 may be a metal material to adjust the work function of the gate structure 150a, and the metal material can be selected depending on the semiconductor device 11a being applied to an NMOS transistor or a PMOS transistor. For example, when the semiconductor device 11a is applied to the NMOS transistor, the work function metal layer 156 may be a metal material with a work function of 3.9 electron volts (eV) to 4.3 eV, such as titanium aluminide (TiAl) or zirconium aluminide (ZrAl), but not limited thereto. When the semiconductor device 11a is applied to the PMOS transistor, the work function metal layer 156 may be a metal material with a work function of 4.8 eV to 5.2 eV, such as titanium nitride (TiN), tantalum nitride (TaN) or tantalum carbide (TaC), but not limited thereto. A material of the low-resistance metal layer 157 may include, for example, copper (Cu), aluminum (Al), tungsten (W), titanium aluminum alloy (TiAl), cobalt tungsten phosphide (CoWP) or a combination thereof, but not limited thereto. The gate structure 150a may further include a barrier layer (not shown) disposed between the work function metal layer 156 and the low-resistance metal layer 157. A material of the barrier layer may include titanium (Ti), titanium nitride (TiN), tantalum (Ta) or tantalum nitride (TaN), but not limited thereto. In other words, in the embodiment, the materials of the gate structure 150a and the gate structure 250 are different. The gate structure 150a includes a metallic conductive material, and the gate structure 250 includes a non-metallic conductive material. However, the present disclosure is not limited thereto. In other embodiment, the non-metallic conductive material of the gate structure 250 in FIG. 4 or FIG. 6 can be replaced with a metallic conductive material by a replacement metal gate process.

Please refer to the right portion of FIG. 4. The present disclosure further provides a semiconductor device 12 including the gate structure 250, the insulating layer 240 and the two source/drain regions 270. The portion 251 of the gate structure 250 is embedded in the substrate 10, and the insulating layer 240 is disposed between the portion 251 of the gate structure 250 and the substrate 10 and encompasses the portion 251 of the gate structure 250. The two source/drain regions 270 are disposed in the substrate 10 and are located at two sides of the gate structure 250, respectively. The insulating layer 240 has a U-shaped profile. The top surface 243 of the insulating layer 240 may be aligned with the top surface 201 of the substrate 10. The insulating layer 240 includes the first layer 241 and the second layer 242. The first layer 241 is disposed on the bottom surface 254 of the gate structure 250, and the second layer 242 is disposed on the side surface 253 of the gate structure 250. Depths (not labeled) of the two source/drain regions 270 in the substrate 10 is deeper than a depth of the insulating layer 240 in the substrate 10. In general, the position of the gate structure 250 having the strongest electric field is located at the edge, such as the edge 255, and the position of each of the source/drain regions 270 having the highest dopant concentration is close to the top surface 201 of the substrate 10. In the present disclosure, with the portion 251 of the gate structure 250 being embedded in the substrate 10 and encompassed by the insulating layer 240, it is beneficial to increase the distance between the position of the gate structure 250 having the strongest electric field and the position of each of the source/drain regions 270 having the highest dopant concentration. Accordingly, it is beneficial to reduce the gate-induced drain leakage (GIDL) and improve the electrical performance of the semiconductor device 12.

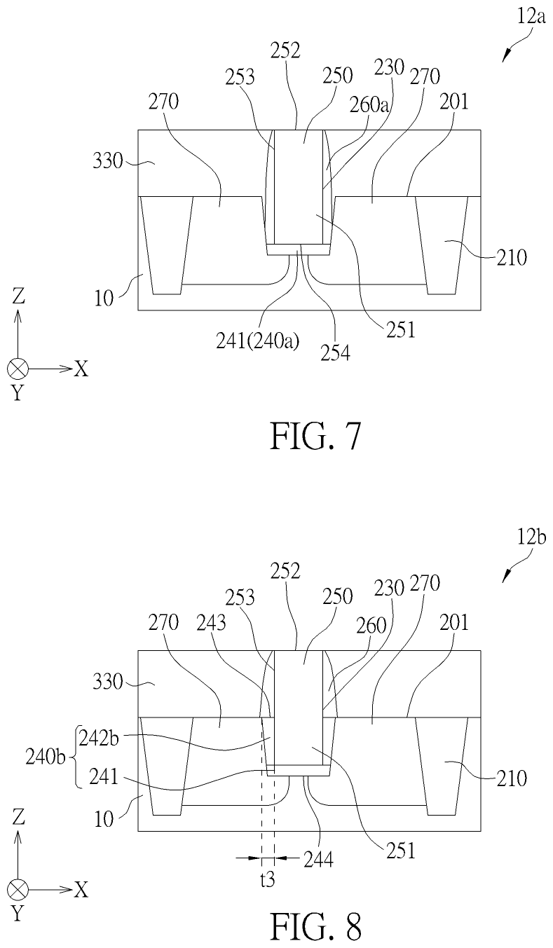

Please refer to FIG. 7, which is a schematic cross-sectional view of a semiconductor device 12a according to further another embodiment of the present disclosure. The main difference between the semiconductor device 12a and the semiconductor device 12 is that the configuration of the insulating layer 240a and the spacer 260a is different from the configuration of the insulating layer 240 and the spacer 260. The insulating layer 240a is disposed on the bottom surface 254 of the gate structure 250 and is located between the gate structure 250 and the substrate 10, and the insulating layer 240a is not disposed on the side surface 253 of the gate structure 250. For example, the second layer 242 (see FIG. 4) of the insulating layer 240 can be removed by an etching process, and only the first layer 241 is reserved as the insulating layer 240a. The rest of the recess 230 is filled with the spacer 260a and the dielectric layer 330. Compared with the semiconductor device 12 in which the spacer 260 only partially covers the side surface 253 (see FIG. 4) of the gate structure 250, the spacer 260a of the semiconductor device 12a completely covers the side surface 253 of the gate structure 250. In other words, the portion of the spacer 260a in the recess 230 and the portion of the dielectric layer 330 filled in the recess 230 have the same function as the second layer 242 of the insulating layer 240. The portion of the spacer 260a in the recess 230, the portion of the dielectric layer 330 filled in the recess 230, and the insulating layer 240a together form an insulating layer (not labeled) disposed between the portion 251 of the gate structure 250 and the substrate 10 and encompasses the portion 251 of the gate structure 250. Thereby, it is also beneficial to reduce the GIDL and improve the electrical performance of the semiconductor device 12a.

Please refer to FIG. 8, which is a schematic cross-sectional view of a semiconductor device 12b according to yet another embodiment of the present disclosure. The main difference between the semiconductor device 12b and the semiconductor device 12 is that the forming timing of the second layer 242b of the insulating layer 240b is different from the forming timing of the second layer 242 of the insulating layer 240. For example, the second layer 242 (See FIG. 4) of the insulating layer 240 can be removed by an etching process and then another second layer 242b may be formed by a deposition process. Thereby, it is beneficial to control the thickness t3 of the second layer 242b. A material of the second layer 242b may be the same as that of the second layer 242. In other embodiment, the insulating layer 240 can be completely removed, and then another insulating layer (not shown) can be formed. For other properties of the semiconductor device 12b, reference may be made to that of the semiconductor device 12, and is omitted herein.

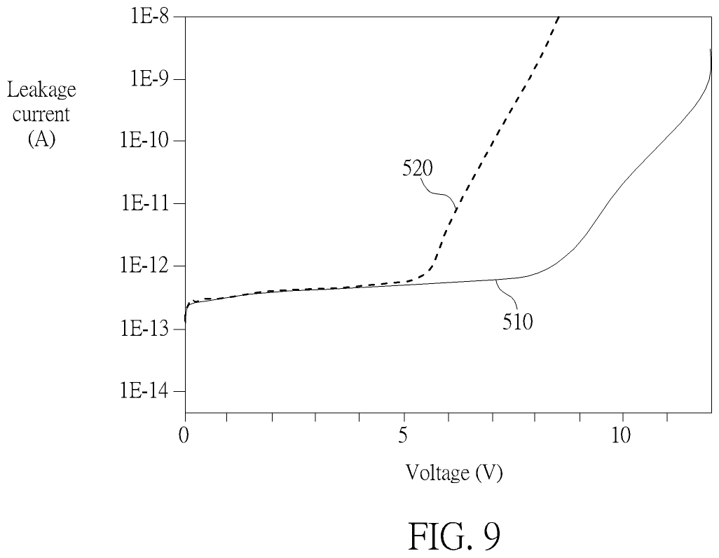

Please refer to FIG. 9, which is a diagram showing a relationship of leakage current and voltage of an example according to the present disclosure and a comparative example, wherein the voltage refers to the voltage that is applied to the drain. The curve 510 and the curve 520 are the experimental results of the semiconductor device of an example according to the present disclosure and a comparative example, respectively. The main difference between the semiconductor device of the example and the comparative example is that in the semiconductor device of the example, a portion of the gate structure of the semiconductor device is embedded in the substrate, and the insulating layer encompasses the portion of the gate structure (which may refer to the structure of the semiconductor device 12), while the gate structure and the insulating layer of the semiconductor device of the comparative example are disposed on the substrate, and the insulating layer is disposed on the bottom surface of the gate structure and is located between the gate structure and the substrate. As shown in FIG. 9, the semiconductor device of the comparative example generates a higher leakage current when a lower voltage is applied to drain. It is obvious that the semiconductor device according to the present disclosure is beneficial to reduce GIDL.

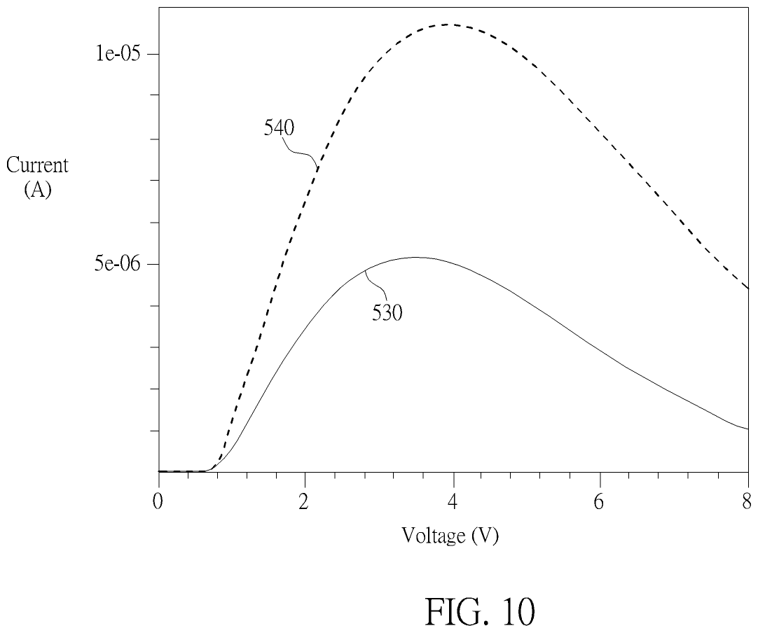

Please refer to FIG. 10, which is a diagram showing a relationship of current and voltage of an example according to the present disclosure and a comparative example, wherein the current refers to the current of the substrate, and the voltage refers to the voltage applied to the gate. The curve 530 and the curve 540 are the experimental results of the semiconductor device of the example according to the present disclosure and the comparative example, respectively. For the main difference of the semiconductor device of the example and the comparative example, reference may be made to the relevant description of FIG. 9. As shown in FIG. 10, when the voltage applied to the gates are the same, a current measured from the substrate of the semiconductor device of the comparative example is higher than that of the substrate of the semiconductor device of the example. It is obvious that the semiconductor device according to the present disclosure has an improved electrical performance.

Compared with the prior art, the present disclosure provides a semiconductor device, a portion of a gate structure is embedded in a substrate, and an insulating layer is used to encompass the portion of the gate structure, which is beneficial to reduce the GIDL caused by the gate structure, and can improve the electrical performance of the semiconductor device. The present disclosure further provides a method for fabricating a semiconductor device. The method can arrange a non-planar transistor and a planar transistors on the same layer, which is beneficial to improve the pattern loading uniformity. A semiconductor device fabricated by the method has an improved pattern loading uniformity, and the semiconductor device includes devices with different driving voltages, wherein a portion of a gate structure of the medium voltage device/high voltage device is embedded in the substrate, which can avoid the drawback of excessively low height of the gate structure due to a thicker gate dielectric layer required by the medium voltage device/high voltage device.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A semiconductor device, comprising:
a gate structure, wherein a portion of the gate structure is embedded in a substrate;
an insulating layer disposed between the portion of the gate structure and the substrate and encompassing the portion of the gate structure; and
two source/drain regions disposed in the substrate and respectively located at two sides of the gate structure.

2. The semiconductor device of claim 1, wherein the insulating layer has a U-shaped profile.

3. The semiconductor device of claim 1, wherein a top surface of the insulating layer is aligned with a top surface of the substrate.

4. The semiconductor device of claim 1, wherein the insulating layer comprises a first layer and a second layer, the first layer is disposed on a bottom surface of the gate structure, and the second layer is disposed on a side surface of the gate structure.

5. A semiconductor device, comprising:
a substrate having a first region and a second region;
a fin structure disposed in the first region;
a first insulating structure disposed in the first region and surrounding the fin structure, wherein a portion of the fin structure protrudes from the first insulating structure;
a first gate structure disposed in the first region and on the fin structure;
a second gate structure disposed in the second region, wherein a portion of the second gate structure is embedded in the substrate; and
an insulating layer disposed between the portion of the second gate structure and the substrate and encompassing the portion of the second gate structure.

6. The semiconductor device of claim 5, further comprising:
a second insulating structure disposed in the second region and surrounding the second gate structure.

7. The semiconductor device of claim 6, wherein a height of the second insulating structure is greater than a height of the first insulating structure.

8. The semiconductor device of claim 5, wherein a top surface of the fin structure is aligned with a top surface of the substrate in the second region.

9. The semiconductor device of claim 5, wherein a top surface of the first gate structure is aligned with a top surface of the second gate structure.

10. The semiconductor device of claim 5, wherein a bottom surface of the first insulating structure is aligned with a bottom surface of the insulating layer.

11. The semiconductor device of claim 5, wherein the insulating layer has a U-shaped profile.

12. The semiconductor device of claim 5, wherein a top surface of the insulating layer is aligned with a top surface of the substrate in the second region.

13. The semiconductor device of claim 5, wherein a structure of the first gate structure is different from a structure of the second gate structure, or a material of the first gate structure is different from a material of the second gate structure.

14. The semiconductor device of claim 5, wherein the first gate structure and the second gate structure comprise a metallic conductive material.

15. The semiconductor device of claim 5, wherein the first gate structure comprises a metallic conductive material, and the second gate structure comprises a non-metallic conductive material.

16. A method for fabricating a semiconductor device, comprising:
providing a substrate having a first region and a second region;
forming a fin structure and a first insulating structure in the first region, wherein the first insulating structure surrounds the fin structure;
forming a temporary insulating structure in the second region;
removing a portion of the first insulating structure, so that a portion of the fin structure protrudes from the first insulating structure;
removing a portion of the temporary insulating structure to form an insulating layer and a recess in the substrate;
forming a first gate structure on the fin structure; and
forming a second gate structure on the insulating layer and in the recess.

17. The method of claim 16, further comprising:
forming a second insulating structure in the second region, wherein the second insulating structure surrounds the second gate structure.

18. The method of claim 17, wherein a height of the second insulating structure is greater than a height of the first insulating structure.

19. The method of claim 16, wherein a top surface of the fin structure is aligned with a top surface of the substrate in the second region.

20. The method of claim 16, wherein in a top surface of the first gate structure is aligned with a top surface of the second gate structure.

21. The method of claim 16, wherein in a bottom surface of the first insulating structure is aligned with a bottom surface of the insulating layer.

22. The method of claim 16, wherein the insulating layer has a U-shaped profile.

23. The method of claim 16, wherein a top surface of the insulating layer is aligned with a top surface of the substrate in the second region.
